(19) United States
(12) Patent Application Publication
(10) Pub. No.: US 2012/0260985 A1
(43) Pub. Date: Oct. 18, 2012

(54) SOLAR CELL

(75) Inventors: Kwang-Soo HUH, Yongin-si (KR); Sang-Cheol PARK, Yongin-si (KR); Jeong-Hoon RYU, Yongin-si (KR); Jung-Gyu NAM, Yongin-si (KR); Sung-Chul KIM, Seoul (KR)

(73) Assignees: SAMSUNG SDI CO., LTD., Yongin-si (KR); Myongji University Industry and Academia Cooperation Foundation, Yongin-si (KR); SAMSUNG ELECTRONICS CO., LTD., Suwon-si (KR)

(21) Appl. No.: 13/295,452

(22) Filed: Nov. 14, 2011

(30) Foreign Application Priority Data
Apr. 18, 2011 (KR) 10-2011-0035463

(51) Int. Cl. H01L 31/0232; H01L 31/0224; B82Y 99/00

(52) U.S. Cl. 136/259; 977/948

(57) ABSTRACT

A solar cell in which the P-type light absorbing layer is thin, and the nanoparticles are disposed. Although the P-type light absorbing layer is thin, the light absorption efficiency may be increased by the use of nanoparticles. Accordingly, the P-type light absorbing layer is formed thin, and thereby the material cost may be reduced and the process time may be shortened.

Also, a solar cell in which the nanoparticles are disposed on the transparent electrode layer or inside the transparent electrode layer, and the size of the nanoparticles and the space between them are controlled such that the light absorption efficiency may be increased, and the nanoparticles are disposed in the N-type light absorbing layer, and the size of the nanoparticles and the space between them are controlled such that the light absorption efficiency may be increased.

### CROSS-REFERENCE TO RELATED APPLICATION

This application claims priority to and the benefit of Korean Patent Application No. 10-2011-0035463 filed on Apr. 18, 2011 which is hereby incorporated by reference for all purposes as if fully set forth herein.

### BACKGROUND OF THE INVENTION

1. Field of the Invention

Exemplary embodiments of the present invention relate to a solar cell.

2. Discussion of the Background

Solar cells convert sunlight energy into electrical energy, and are important clean energy or next-generation energy sources for replacing fossil energy that causes a greenhouse effect due to discharge of CO₂ and nuclear energy that contaminates the earth environment, such as through air pollution due to radioactive waste.

The solar cells basically generate electricity using two kinds of semiconductors: a P-type semiconductor and an N-type semiconductor. When the solar cells are used as a light absorbing layer, they are classified into various types depending on the materials used.

The solar cell has a general structure in which a front transparent conductive layer, a PN layer, and a rear reflecting electrode layer are deposited on a substrate in sequence. When sunlight is incident to the solar cell of the structure, electrons are collected on the N layer and holes are collected on the P layer thereby generating a current.

A portion of the solar light is reflected while passing through the transparent electrode such that light absorption efficiency of the solar cell is decreased.

The above information disclosed in this Background section is only for enhancement of understanding of the background of the invention and therefore it may contain information that does not form the prior art that is already known in this country to a person of ordinary skill in the art.

### SUMMARY OF THE INVENTION

Exemplary embodiments of the present invention provide a solar cell with increased light absorption efficiency.

Additional features of the invention will be set forth in the description which follows, and in part will be apparent from the description, or may be learned by practice of the invention.

An exemplary embodiment of the present invention discloses a solar cell including: a first reflective electrode layer and a second transparent electrode layer facing each other; a P-type light absorbing layer and a N-type light absorbing layer disposed between the first reflective electrode layer and the second transparent electrode layer; and a plurality of nanoparticles disposed at an interface between the first reflective electrode layer and the P-type light absorbing layer.

An exemplary embodiment of the present invention also discloses a solar cell including: a first reflective electrode layer and a second transparent electrode layer facing each other; a light absorbing layer between the first reflective electrode layer and the second transparent electrode layer; and a plurality of nanoparticles disposed on the second transparent electrode layer, wherein a space between the nanoparticles is less than about 1000 nm, and the size of the nanoparticles is more than about 50 nm.

An exemplary embodiment of the present invention also discloses a solar cell including: a first reflective electrode layer and a second transparent electrode layer facing each other; a light absorbing layer between the first reflective electrode layer and the second transparent electrode layer; and a plurality of nanoparticles disposed inside the second transparent electrode layer, wherein a space between the nanoparticles is less than about 1000 nm, and the size of the nanoparticles is more than about 50 nm.

An exemplary embodiment of the present invention also discloses a solar cell includes: a first reflective electrode layer and a second transparent electrode layer facing each other; a P-type light absorbing layer and an N-type light absorbing layer disposed between the first reflective electrode layer and the second transparent electrode layer; and a plurality of nanoparticles disposed inside the N-type light absorbing layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a solar cell according to an exemplary embodiment of the present invention.

FIG. 2 is a cross-sectional view of a solar cell according to an exemplary embodiment of the present invention.

FIG. 3A is a graph showing the light absorption ratio of a solar cell according to an exemplary embodiment of the present invention.

FIG. 3B is a graph of a light absorption ratio of a solar cell according to an exemplary embodiment of the present invention.

FIG. 4 is a graph of a light absorption ratio of a solar cell according to an exemplary embodiment of the present invention.

FIG. 5 is a graph of a light absorption ratio of a solar cell according to an exemplary embodiment of the present invention.

FIG. 6 is a cross-sectional view of a solar cell according to an exemplary embodiment of the present invention.

FIG. 7A depicts a table of a light absorption efficiency of a solar cell according to an exemplary embodiment.

FIG. 7B is a graph showing a light absorption efficiency of a solar cell according to an exemplary embodiment of the present invention.

FIG. 8 is a cross-sectional view of a solar cell according to an exemplary embodiment of the present invention.

FIG. 9 is a cross-sectional view of a solar cell according to an exemplary embodiment of the present invention.

FIG. 10A depicts a table of a light absorption efficiency of a solar cell according to an exemplary embodiment.

FIG. 10B is a graph of a light absorption efficiency of a solar cell according to an exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. Further, it will be understood that for the purposes of this disclosure, “at least one of,” and similar language, will be interpreted to indicate any combination of the enumerated elements following the respective language, including combinations of multiples of the enumerated elements. For example, “at least one of X, Y, and Z” will be construed to indicate X only, Y only, Z only, or any combination of two or more items X, Y, and Z (e.g., XYZ, XZ, YZ).

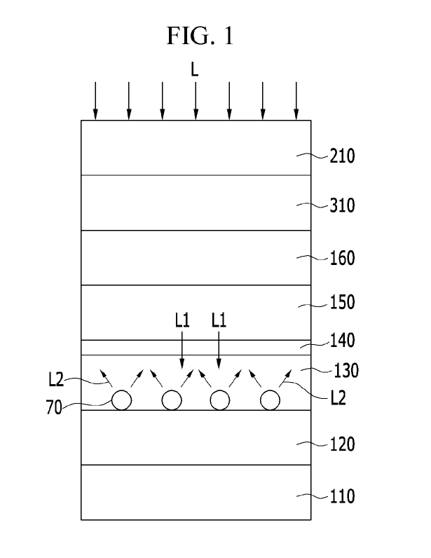

A solar cell according to an exemplary embodiment of the present invention will be described with reference to FIG. 1. FIG. 1 is a cross-sectional view of a solar cell according to an exemplary embodiment of the present invention.

Referring to FIG. 1, a solar cell, according to an exemplary embodiment of the present invention, includes a first electrode layer 120 disposed on a substrate 110, a P-type light absorbing layer 130 disposed on the first electrode layer 120, a plurality of nanoparticles 70 disposed in the P-type light absorbing layer 130, a buffer layer 140 disposed on the P-type light absorbing layer 130, a N-type light absorbing layer 150 disposed on the buffer layer 140, a second electrode layer 160 disposed on the N-type light absorbing layer 150, a sealing layer 310 disposed on the second electrode layer 160, and an overcoat 210 disposed on the sealing layer 310.

The first electrode layer 120 may include a metal, such as, tungsten, tantalum, titanium, gold, and molybdenum.

The P-type light absorbing layer 130 has a low electron density and a high hole density, and may be a CI(G)S group light absorbing layer in which CuIn(Ga)Se₂ is the P-type semiconductor. In an exemplary embodiment, the thickness of the P-type light absorbing layer 130 of the solar cell may be about 0.2 μm to about 1.5 μm, which is very thin compared with the thickness of the P-type light absorbing layer of the conventional art.

The nanoparticle 70 may be made of at least one of: gold (Au), silver (Ag), platinum (Pt), aluminum (Al), tungsten (W), or vanadium (V). Light L incident to the solar cell at the overcoat 210 progresses to the first electrode layer 120 and the nanoparticle 70 scatters a portion of the light L1 that is not absorbed by the P-type light absorbing layer 130. The scattered light L2, scattered by the nanoparticles 70, may be absorbed in the P-type light absorbing layer 130, thereby increasing the efficiency of absorption of the incident light L. The nanoparticles 70, according to an exemplary embodiment, are disposed in the absorbing layer 130, and particularly, may be disposed at the interface between the P-type light absorbing layer 130 and the first electrode layer 120. The nanoparticles 70 may be arranged with a space of less than about 1000 nm between them, in detail less than about 600 nm, and the size of the nanoparticles 70 may be more than about 60 nm, in detail more than about 100 nm.

The buffer layer 140 is disposed between the P-type light absorbing layer 130 and the N-type light absorbing layer 150, thereby compensating for the interface deterioration according to a PN heterojunction.

The N-type light absorbing layer 150 has an N-type semiconductor characteristic and may include zinc oxide (ZnO).

The second electrode layer 160 is made of a transparent conductor, such as, zinc oxide, indium tin oxide (ITO), etc.

The sealing layer 310 is disposed on the second electrode layer 160 and protects the second electrode layer from the overcoat 210. The sealing layer 310 may include ethylene vinyl acetate (EVA).

The solar cell, according to an exemplary embodiment, includes a plurality of nanoparticles 70 disposed at the interface between the thin P-type light absorbing layer 130 and the first electrode layer 120. Accordingly, a portion of light L1, i.e., light from among the incident light L that progresses to the P-type light absorbing layer 130 and that is not absorbed by the P-type light absorbing layer 130, is scattered (L2). The scattered light L2 progresses through the P-type light absorbing layer 130, having a thin thickness, and may be absorbed therein, thereby increasing the light absorption efficiency of the solar cell. In an exemplary embodiment, if forming the thin P-type light absorbing layer 130, the light absorption efficiency may be increased by a plurality of nanoparticles 70, and because the P-type light absorbing layer 130 is formed thin, the material cost of formation may be reduced and the production time may be shortened.

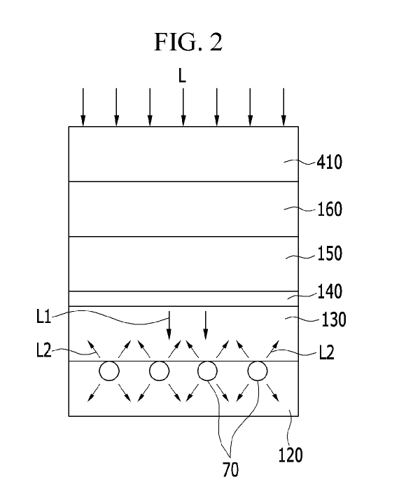

A solar cell, according to an exemplary embodiment of the present invention, will be described with reference to FIG. 2. FIG. 2 is a cross-sectional view of a solar cell according to an exemplary embodiment of the present invention.

Referring to FIG. 2, a solar cell, according to an exemplary embodiment, is similar to the solar cell of the exemplary embodiment described with reference to FIG. 1. The solar cell includes a reflective first electrode layer 120, a plurality of nanoparticles 70 dispersed in the first electrode layer 120, a P-type light absorbing layer 130, a buffer layer 140, an N-type light absorbing layer 150, a second electrode layer 160, and a substrate 410. The solar cell, according to an exemplary embodiment, has a superstrate structure, and a plurality of nanoparticles 70 are disposed in the first electrode layer 12.

The thickness of the P-type light absorbing layer 130 of the solar cell, according to an exemplary embodiment of the present invention, is in the range of about 0.2 μm to about 1.5 μm, which is thinner than the thickness of the P-type light absorbing layer 130 of the conventional art.

The nanoparticles 70 scatter portions of the light L1, i.e., light that is not absorbed by the P-type light absorbing layer 130 and progresses into the first electrode layer 120. The scattered light L2 may be absorbed in the P-type light absorbing layer 130, thereby increasing the efficiency of absorption of the incident light L. The nanoparticles 70, according to an exemplary embodiment, may be disposed in the first electrode layer 120, and particularly, may be disposed at the interface between the P-type light absorbing layer 130 and the first electrode layer 120. The nanoparticles 70 may be disposed with a space of less than about 1000 nm between them, and in detail, about 600 nm, and the size of the nanoparticles 70 may be more than about 60 nm, and in detail, about 100 nm.

The solar cell, according to an exemplary embodiment, includes a plurality of nanoparticles 70 disposed at the interface between the thin P-type light absorbing layer 130, and the first electrode layer 120. Accordingly, a portion of the light L1, i.e., light from among the incident light L that progresses to the P-type light absorbing layer 130 and that is not absorbed by the P-type light absorbing layer 130, is scattered (L2). A portion of the scattered light L2 progresses into the P-type light absorbing layer 130 and may be absorbed therein, thereby increasing the light absorption efficiency of the solar cell. In an exemplary embodiment, although the P-type light absorbing layer 130 is thin, the light absorption efficiency of the solar cell may be increased by use of a plurality of nanoparticles 70, and the layer forming the P-type light absorbing layer 130 is thin thereby reducing material costs and production time.

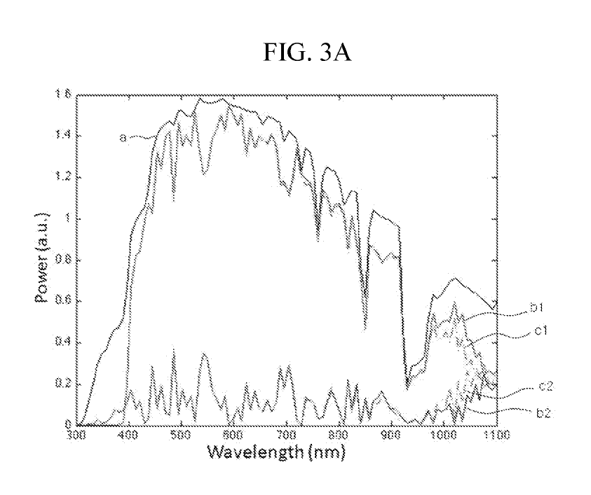

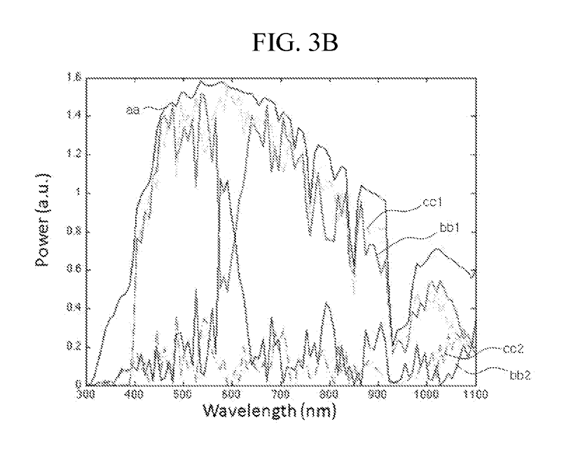

A light absorption ratio of a solar cell according to an exemplary embodiment of the present invention will be described with reference to FIG. 3A and FIG. 3B. FIG. 3A is a graph showing the light absorption ratio of a solar cell according to an exemplary embodiment of the present invention. FIG. 3B is a graph of a light absorption ratio of a solar cell according to an exemplary embodiment of the present invention.

In the exemplary embodiments depicted in FIG. 3A and FIG. 3B, the solar cell includes the first electrode layer 120, the P-type light absorbing layer 130 disposed on the first electrode layer 120, the buffer layer 140 disposed on the P-type light absorbing layer 130, the N-type light absorbing layer 150 disposed on the buffer layer 140, and the second electrode layer 160 disposed on the N-type light absorbing layer 150. The thickness of the P-type light absorbing layer 130 may be about 0.5 μm, which is thinner than the P-type light absorbing layer of the conventional solar cell. Referring to FIG. 3A, the light absorption ratio and reflectance ratio for a case of forming a plurality of nanoparticles 70 in the first electrode layer 120 are compared to a case in which nanoparticles 70 are not formed. Referring to FIG. 3B, the light absorption ratio and reflectance ratio for a case in which the nanoparticles are formed in the second electrode layer 160 are compared to a case in which the nanoparticles are not formed In FIG. 3A and FIG. 3B, the nanoparticles are made of gold, disposed with space of about 400 nm therebetween, and the size of the nanoparticles is about 150 nm.

Referring to FIG. 3A, the absorption b1 and the reflection b2 are for the incident light “a” of the case of forming a plurality of nanoparticles 70 in the first electrode layer 120 and the absorption cl and the reflection c2 are for the case in which nanoparticles 70 are not formed, like the conventional solar cell. In an exemplary embodiment of the present invention, it may be confirmed that the absorption b1 of the case of forming a plurality of nanoparticles 70 in the first electrode layer 120 is larger than the absorption of the conventional solar cell cl, and the reflection b2 is smaller than the reflection of the conventional solar cell c2. Particularly, the difference in a high wavelength region is very large. The absorption efficiency for the incident light “a” is calculated based on the absorptions b1 and cl and the reflections b2 and c2. The absorption efficiency of the case of forming a plurality of nanoparticles 70 in the first electrode layer 120 is about 27.828%, and the absorption efficiency of the case in which a plurality of nanoparticles 70 are not formed, like the conventional solar cell, is about 26.963%. In this way, in an exemplary embodiment of the present invention, although the thickness of the P-type light absorbing layer 130 is about 0.5 μm, which is thinner than the P-type light absorbing layer of the conventional solar cell, if a plurality of nanoparticles 70 are formed in the first electrode layer 120, the light absorption efficiency may be increased.

Referring to FIG. 3B, the absorption bb1 and the reflection bb2 are for the incident light “aa” of the case in which the thickness of the P-type light absorbing layer 130 is about 0.5 μm, which is thinner than the P-type light absorbing layer of the conventional solar cell, and the nanoparticles 70 are formed in the second electrode layer 160. The absorption cc1 and the reflection cc2 are for the incident light “aa” of the case in which the nanoparticles are not formed and the thickness of the P-type light absorbing layer 130 is about 0.5 μm, which is thinner than the P-type light absorbing layer of the conventional solar cell. In a specific wavelength region, for example, in the wavelength region between about 550 nm to about 650 nm, it may be confirmed that the reflection bb2 is larger than the absorption bb1. The efficiency for the absorption of incident light “aa” is calculated based on the absorptions bb1 and cc1 and the reflections bb2 and cc2. The absorption efficiency of the incident light is about 24.192% in the case in which the P-type light absorbing layer is formed thinner than the conventional solar cell, and nanoparticles are formed in the second electrode layer 160. The absorption efficiency of the light in the case in which nanoparticles are not formed is about 26.963%. In other words, in the case in which the thickness of the P-type light absorbing layer 130 is thinner than the P-type light absorbing layer of the conventional solar cell, if nanoparticles are formed in the second electrode layer 160 it may be confirmed that the absorption efficiency of the incident light is decreased.

In an exemplary embodiment, if the thickness of the P-type light absorbing layer 130 is thinner than the P-type light absorbing layer of the conventional solar cell and the nanoparticles 70 are formed in the first electrode layer 120, the absorption efficiency of the incident light may be increased.

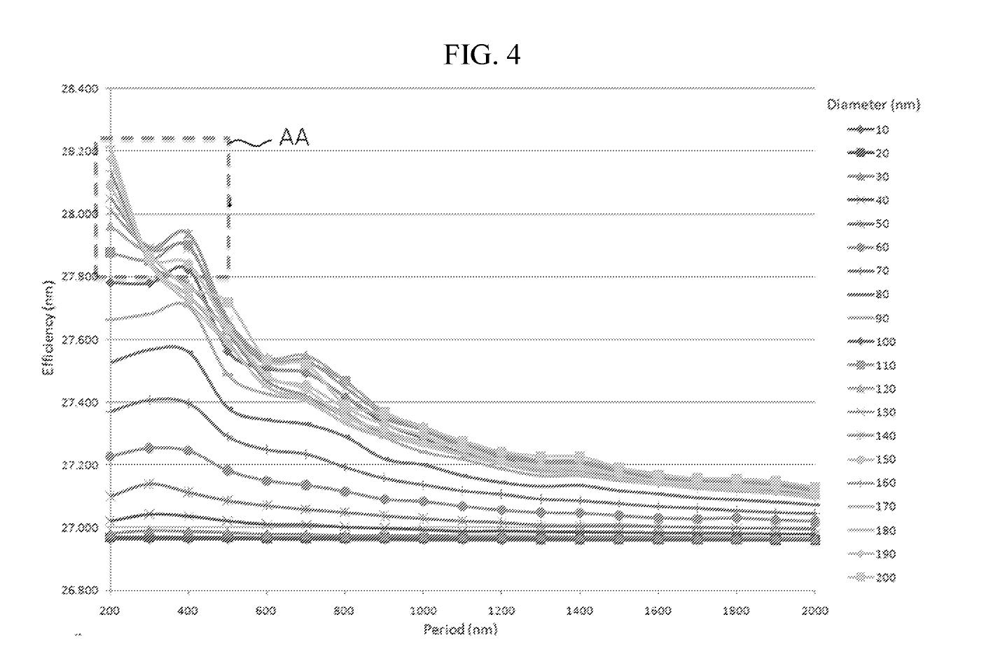

A light absorption ratio of a solar cell, according to an exemplary embodiment of the present invention, will be described with reference to FIG. 4. FIG. 4 is a graph showing a light absorption ratio of a solar cell according to an exemplary embodiment of the present invention.

In the exemplary embodiments depicted in FIG. 4, a solar cell is formed. In detail, the P-type light absorbing layer has a thickness of about 0.5 μm, and a plurality of nanoparticles 70 are formed in the first electrode layer 120 while varying the size of the nanoparticles 70 and the space between the nanoparticles 70. In FIG. 4, the absorption efficiency of light in the exemplary solar cells is measured and compared with the case in which the nanoparticles are not formed in a solar cell.

Referring to FIG. 4, the absorption efficiency of the light of the case in which nanoparticles are not formed is about 26.963%, the absorption efficiency of the light of the case in which nanoparticles are formed is higher. In a case in which the space between the nanoparticles is less than about 1000 nm, it may be confirmed that the absorption efficiency of the light is increased. Also, it may be confirmed that the absorption efficiency of the light is large in the case in which the size of the nanoparticles is about 60 nm. In the graph of FIG. 4, a portion in which there is a very large increase in the absorption efficiency of the light is indicated by “AA.” Thus, if the P-type light absorbing layer is formed with a thickness of about 0.5 μm, the size of the nanoparticles is more than about 60 nm and the space between the nanoparticle is less than 1000 nm, it may be confirmed that the increase in light absorption efficiency is large.

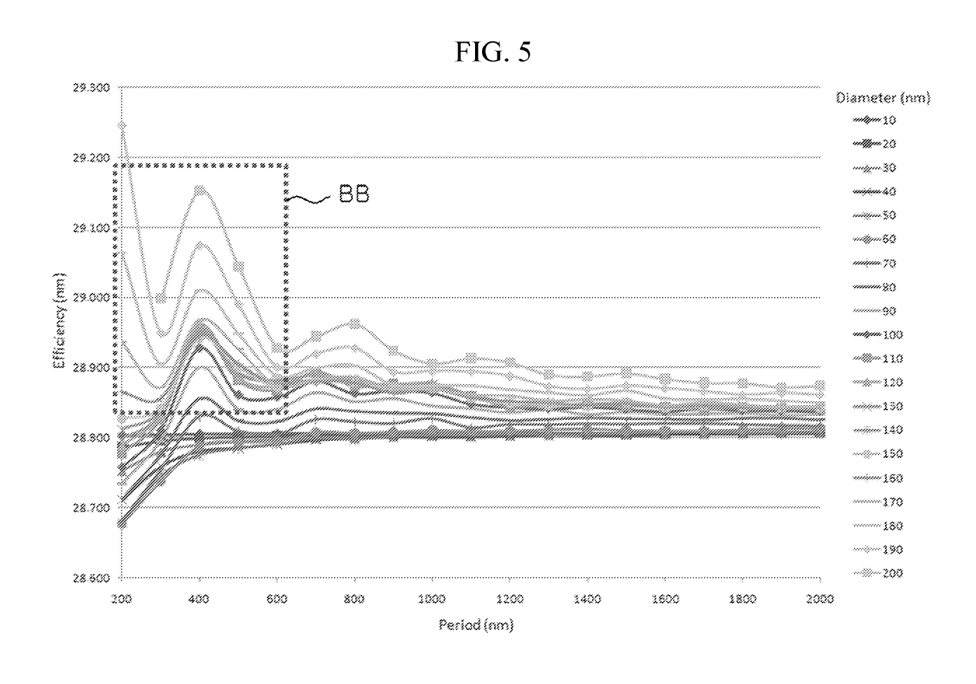

A light absorption ratio of a solar cell according to an exemplary embodiment of the present invention will be described with reference to FIG. 5. FIG. 5 is a graph of a light absorption ratio of a solar cell according to an exemplary embodiment of the present invention.

In the exemplary embodiment depicted in FIG. 5, a solar cell is formed. In detail, the P-type light absorbing layer is formed with a thickness of about 1.0 μm and a plurality of nanoparticles 70 are formed in the first electrode layer 120. In FIG. 5, the absorption efficiency of light in the exemplary solar cells is measured while varying the size and the space between the nanoparticles 70 and compared with the case in which the nanoparticles are not formed in a solar cell.

Referring to FIG. 5, the light absorption efficiency of the case in which nanoparticles are not formed is about 28.8061%, the light absorption efficiency of the case in which nanoparticles are formed is higher than that. In the case in which the space between the nanoparticle is less than about 1000 nm, it may be confirmed that a large increase in the light absorption efficiency is observed. Also, in the case in which the size of the nanoparticles more than about 100 nm, it may be confirmed that a large increase in the light absorption efficiency is observed. In the graph of FIG. 5, a portion in which the increase in the light absorption efficiency is very large is indicated by “BB.” Thus, if forming the P-type light absorbing layer with a thickness of about 1.0 μm, the size of the nanoparticles is more than about 100 nm and the space between the nanoparticles is less than about 1000 nm, it may be confirmed that the increase in the light absorption efficiency is large.

In an exemplary embodiment, in the case in which the P-type light absorbing layer is formed thinly compared with that of the conventional solar cell and the nanoparticles are formed in the first electrode layer, it may be confirmed that the light absorption efficiency is increased. In the case in which the space between the nanoparticles is less than about 1000 nm, in detail, about 600 nm, and the size of the nanoparticles is more than about 60 nm, in detail about 100 nm, it may be confirmed that the light absorption efficiency is increased largely.

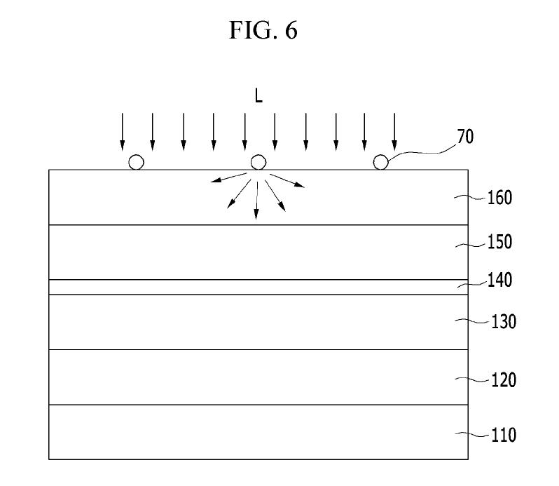

A solar cell according to an exemplary embodiment of the present invention will be described with reference to FIG. 6. FIG. 6 is a cross-sectional view of a solar cell according to an exemplary embodiment of the present invention.

Referring to FIG. 6, the solar cell according to an exemplary embodiment of the present invention includes the first electrode layer 120 disposed on the substrate 110, the P-type light absorbing layer 130 disposed on the first electrode layer 120, the buffer layer 140 disposed on the P-type light absorbing layer 130, the N-type light absorbing layer 150 disposed on the buffer layer 140, the second electrode layer 160 disposed on the N-type light absorbing layer 150, and nanoparticles 70 disposed on the second electrode layer 160.

The first electrode layer 120 may include a metal, such as, at least one of: tungsten, tantalum, titanium, and gold, and in detail, may include molybdenum.

The P-type light absorbing layer 130 has a low electron density and a high hole density, and may be a CI(G)S group light absorbing layer in which CuIn(Ga)Se₂ is the P-type semiconductor.

The buffer layer 140 is disposed between the P-type light absorbing layer 130 and the N-type light absorbing layer 150, thereby compensating for the interface deterioration according to a PN heterojunction.

The N-type light absorbing layer 150 has an N-type semiconductor characteristic and may include ZnO.

The second electrode layer 160 is made of a transparent conductor, such as, zinc oxide, indium tin oxide (ITO), etc.

The nanoparticles 70 may be made of at least one of: gold (Au), silver (Ag), platinum (Pt), aluminum (Al), tungsten (W), or vanadium (V). Light L incident to the solar cell progresses to the second electrode layer 160 and the nanoparticles 70 scatter a portion of the light that is reflected by the second electrode layer 160 from among the incident light L. The scattered light may be absorbed by the N-type light absorbing layer 150 or P-type light absorbing layer 130, thereby increasing the light absorption efficiency. The space between the nanoparticles 70 may be less than about 1000 nm, in detail, in the range of about 200 nm to 1000 nm, and the size of the nanoparticles may be more than about 50 nm, in detail in the range of about 50 nm to 100 nm.

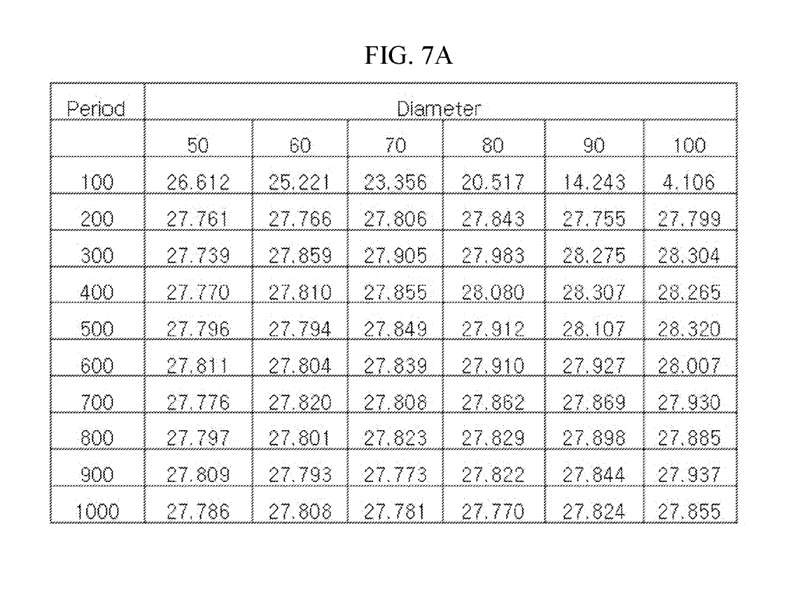

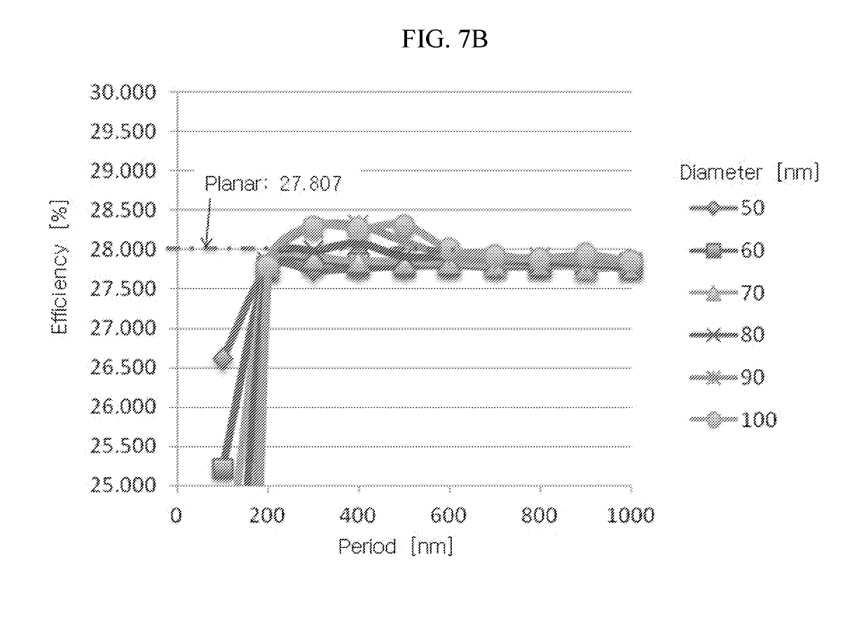

A light absorption efficiency of a solar cell according to an exemplary embodiment of the present invention will be described with reference to FIG. 7A and FIG. 7B. FIG. 7A depicts a table of a light absorption efficiency of a solar cell according to an exemplary embodiment. FIG. 7B is a graph showing a light absorption efficiency of a solar cell according to an exemplary embodiment of the present invention.

In the exemplary embodiment depicted in FIG. 7A and FIG. 7B, like the exemplary embodiment shown in FIG. 6, the solar cell includes the nanoparticles 70 disposed on the second electrode layer 160. The incident light absorption efficiency is calculated while varying the space between the nanoparticles and the size of the particles, and is compared with the case in which the nanoparticles are not formed.

Referring to FIG. 7A and FIG. 7B, if the space between the nanoparticles is in the range of about 200 nm to 1000 nm and the size of the nanoparticles is in the range of about 50 nm to 100 nm, it may be confirmed that the light absorption efficiency is increased compared with the case in which the nanoparticles 70 are not formed, which has a 27.807% incident light absorption efficiency.

In an exemplary embodiment of the present invention, the nanoparticles 70 are formed on the second electrode layer 160, the space between the nanoparticles is in the range of about 200 nm to 1000 nm, and the size of the nanoparticles is in the range of about 50 nm to 100 nm. It may be confirmed that the light absorption efficiency of the solar cell is increased compared with a conventional solar cell.

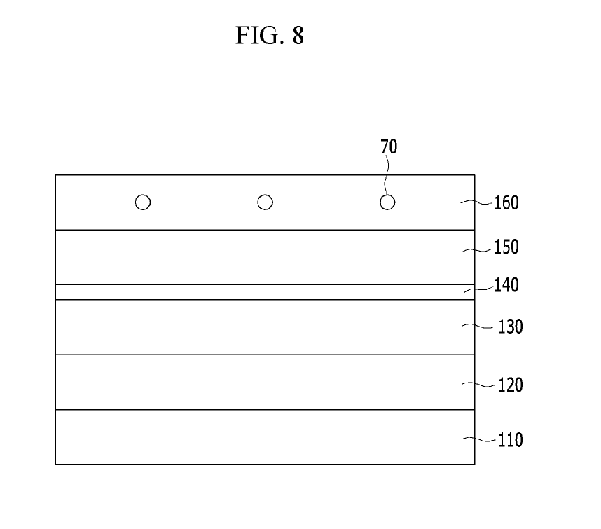

A solar cell according to an exemplary embodiment of the present invention will be described with reference to FIG. 8. FIG. 8 is a cross-sectional view of a solar cell according to an exemplary embodiment of the present invention.

Referring to FIG. 8, the solar cell according to an exemplary embodiment of the present invention includes the first electrode layer 120 disposed on the substrate 110, the P-type light absorbing layer 130 disposed on the first electrode layer 120, the buffer layer 140 disposed on the P-type light absorbing layer 130, the N-type light absorbing layer 150 disposed on the buffer layer 140, the second electrode layer 160 disposed on the N-type light absorbing layer 150, and the nanoparticles 70 disposed inside the second electrode layer 160. The space between the nanoparticles 70 may be less than about 1000 nm, in detail in the range of about 200 nm to 1000 nm, and the size of the nanoparticles may be more than about 50 nm, in detail in the range of about 50 nm to 100 nm.

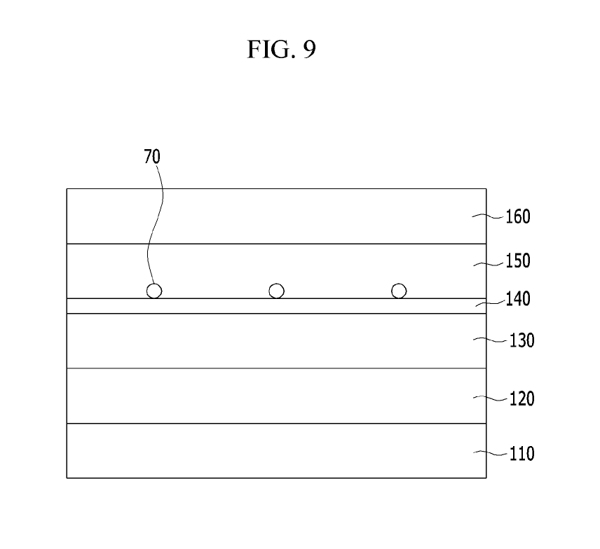

A solar cell according to an exemplary embodiment of the present invention will be described with reference to FIG. 9. FIG. 9 is a cross-sectional view of a solar cell according to an exemplary embodiment of the present invention.

Referring to FIG. 9, the solar cell according to an exemplary embodiment of the present invention includes the first electrode layer 120 disposed on the substrate 110, the P-type light absorbing layer 130 disposed on the first electrode layer 120, the buffer layer 140 disposed on the P-type light absorbing layer 130, the N-type light absorbing layer 150 disposed on the buffer layer 140, the nanoparticles 70 inside the N-type light absorbing layer 150, and the second electrode layer 160 disposed on the N-type light absorbing layer 150.

The space between the nanoparticles 70 may be in the range of about 100 nm to about 400 nm, and the size of the nanoparticles 70 may be in the range of about 10 nm to about 40 nm.

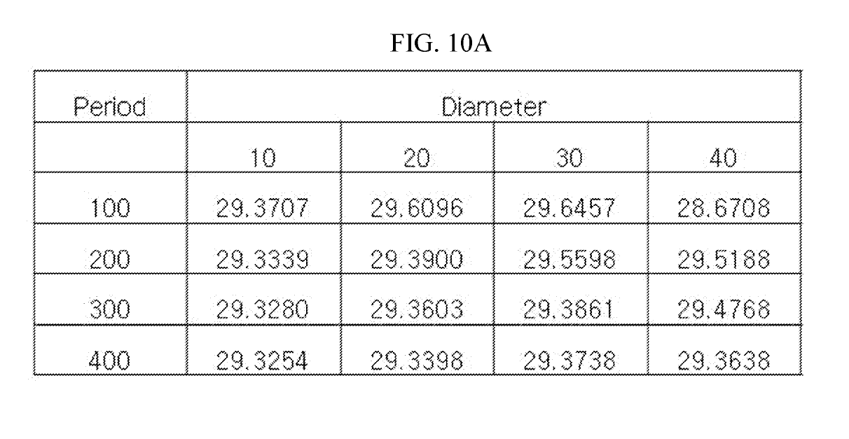

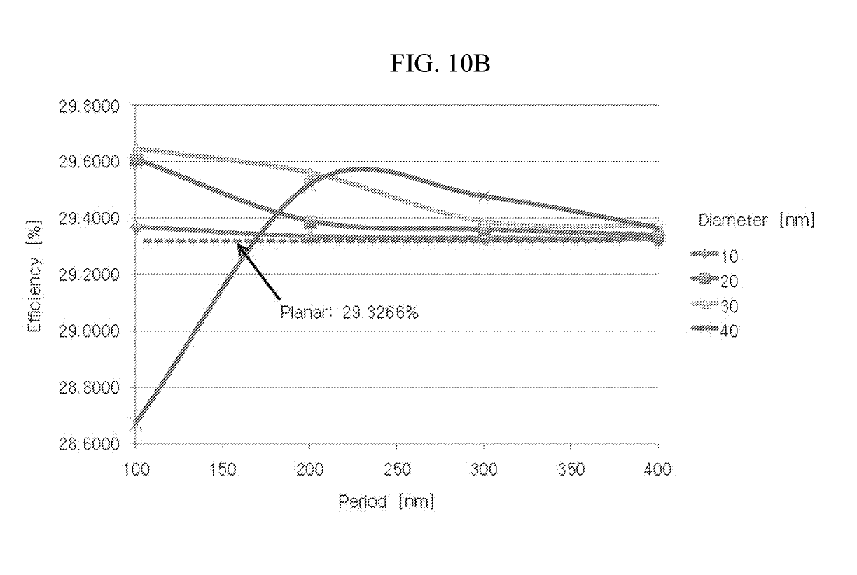

A light absorption efficiency of a solar cell according to an exemplary embodiment of the present invention will be described with reference to FIG. 10A and FIG. 10B. FIG. 10A depicts a table of a light absorption efficiency of a solar cell according to an exemplary embodiment. FIG. 10B is a graph showing a light absorption efficiency of a solar cell according to an exemplary embodiment of the present invention.

In the exemplary embodiment, like the exemplary embodiment shown in FIG. 9, the solar cell includes the nanoparticles 70 disposed inside the N-type light absorbing layer 150. The incident light absorption efficiency is calculated while changing the space between the nanoparticles 70 and the size of the particles and is compared with the case in which the nanoparticles 70 are not formed.

Referring to FIG. 10A and FIG. 10B, if the space between the nanoparticles is in the range of about 100 nm to about 400 nm, and the size of the nanoparticles is in the range of about 10 nm to about 40 nm, it may be confirmed that the light absorption efficiency is increased compared with the case in which the nanoparticles 70 are not formed, which has a 29.3266% incident light absorption efficiency.

In an exemplary embodiment of the present invention, if the solar cell including the nanoparticles 70 disposed inside the N-type light absorbing layer 150 is formed, the space between the nanoparticles is in the range of about 100 nm to about 400 nm, and the size of the nanoparticles is in the range of about 10 nm to about 40 nm. Referring to FIG. 10B, it may be confirmed that the light absorption efficiency of the solar cell may be increased compared with a conventional solar cell.

Although exemplary embodiments described here in disclose nanoparticles in one layer of an exemplary solar cell, aspects of the present invention are not limited thereto, and nanoparticles may be formed in two or more layers.

In exemplary embodiments, the solar cell's P-type light absorbing layer is thin, and the nanoparticles are disposed in the solar cell. Although the P-type light absorbing layer is thin, the light absorption efficiency may be increased by the use of nanoparticles. Accordingly, the layer forming the P-type light absorbing layer is formed thin, thereby reducing material costs and a production time may be shortened.

Also, in the solar cell according to exemplary embodiments of the present invention, the nanoparticles are disposed on the transparent electrode layer or inside the transparent electrode layer, and the size of the nanoparticles and the space between them are controlled such that the light absorption efficiency may be increased, and the nanoparticles are disposed in the N-type light absorbing layer, and the size of the nanoparticles and the space between them are controlled such that the light absorption efficiency may be increased.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A solar cell comprising:
a first reflective electrode layer and a second transparent electrode layer facing each other;
a P-type light absorbing layer and a N-type light absorbing layer disposed between the first reflective electrode layer and the second transparent electrode layer; and
a plurality of nanoparticles disposed at an interface between the first reflective electrode layer and the P-type light absorbing layer.

2. The solar cell of claim 1, wherein
the P-type light absorbing layer has a thickness of about 0.2μm to about 1.5 μm.

3. The solar cell of claim 2, wherein
the thickness of the P-type light absorbing layer is about 0.5 μm.

4. The solar cell of claim 3, wherein
a space between the nanoparticles is less than about 1000 nm, and the size of the nanoparticles is more than about 60 nm.

5. The solar cell of claim 2, wherein
the thickness of the P-type light absorbing layer is about 1.0 μm.

6. The solar cell of claim 5, wherein
the space between the nanoparticles is less than about 1000 nm, and the size of the nanoparticles is more than about 100 nm.

7. The solar cell of claim 1, wherein
the space between the nanoparticles is less than about 1000 nm, and the size of the nanoparticle is more than about 60 nm.

8. The solar cell of claim 1, wherein
the space between the nanoparticles is less than about 1000 nm, and the size of the nanoparticles is more than about 100 nm.

9. The solar cell of claim 1, wherein
the nanoparticles include at least one of: gold (Au), silver (Ag), platinum (Pt), aluminum (Al), tungsten (W), and vanadium (V).

10. A solar cell comprising:
a first reflective electrode layer and a second transparent electrode layer facing each other;
a light absorbing layer between the first reflective electrode layer and the second transparent electrode layer; and
a plurality of nanoparticles disposed on the second transparent electrode layer,
wherein a space between the nanoparticles is less than about 1000 nm, and the size of the nanoparticles is more than about 50 nm.

11. The solar cell of claim 10, wherein
the space between the nanoparticles is in the range of about 200 nm to about 1000 nm, and the size of the nanoparticles is in the range of about 50 nm to about 100 nm.

12. The solar cell of claim 11, wherein
the nanoparticles include at least one of: gold (Au), silver (Ag), platinum (Pt), aluminum (Al), tungsten (W), and vanadium (V).

13. A solar cell comprising:
a first reflective electrode layer and a second transparent electrode layer facing each other;
a light absorbing layer between the first reflective electrode layer and the second transparent electrode layer; and
a plurality of nanoparticles disposed inside the second transparent electrode layer,
wherein a space between the nanoparticles is less than about 1000 nm, and the size of the nanoparticles is more than about 50 nm.

14. The solar cell of claim 13, wherein
the space between the nanoparticles is in the range of about 200 nm to about 1000 nm, and the size of the nanoparticles is in the range of about 50 nm to about 100 nm.

15. The solar cell of claim 14, wherein
the nanoparticles include at least one of: gold (Au), silver (Ag), platinum (Pt), aluminum (Al), tungsten (W), and vanadium (V).

16. A solar cell comprising:
a first reflective electrode layer and a second transparent electrode layer facing each other;
a P-type light absorbing layer and an N-type light absorbing layer disposed between the first reflective electrode layer and the second transparent electrode layer; and
a plurality of nanoparticles disposed inside the N-type light absorbing layer.

17. The solar cell of claim 16, wherein
a space between of the nanoparticles is in the range of about 100 nm to about 400 nm, and the size of the nanoparticles is in the range of about 10 nm to about 40 nm.

18. The solar cell of claim 17, wherein
the nanoparticles include at least one of: gold (Au), silver (Ag), platinum (Pt), aluminum (Al), tungsten (W), and vanadium (V).
